(19) United States
(12) Patent Application Publication
(10) Pub. No.: US 2026/0280525 A1
(43) Pub. Date: Sep. 17, 2026

(54) LOW-LOSS NON-ADJACENT-BAND REJECTION TOPOLOGIES USING BAW RESONATORS

(71) Applicant: Qorvo US, Inc., Greensboro, NC (US)

(72) Inventor: José Enrique Varela Campelo, Altamonte Springs, FL (US)

(21) Appl. No.: 19/469,811

(22) PCT Filed: Mar. 27, 2024
(86) PCT No.: PCT/US2024/021565

§ 371 Date: Sep. 26, 2025

Related U.S. Application Data
(60) Provisional application No. 63/497,211, filed on Apr. 20, 2023.
(60) Provisional application No. 63/520,662, filed on Aug. 21, 2023.

(51) Int. Cl. H03H 9/56

(52) U.S. Cl. CPC H03H 9/56

(57) ABSTRACT

Filter circuitry (16, 18, 26) having a passband filter configured to pass a desired frequency band, and a filter coupled to the passband filter is disclosed. The filter has at least one acoustic wave resonator (RES1 . . . RES9) configured to attenuate an undesired frequency band that is nonadjacent to the desired frequency band. The at least one acoustic resonator behaves as a capacitor at the passband frequencies of the coupled filter. The at least one acoustic resonator may be a bulk acoustic wave (BAW) resonator.

### RELATED APPLICATIONS

This application claims the benefit of provisional patent application Ser. No. 63/520,662, filed Aug. 21, 2023, and claims the benefit of provisional patent application Ser. No. 63/497,211, filed Apr. 20, 2023, the disclosures of which are hereby incorporated herein by reference in their entireties.

### FIELD OF THE DISCLOSURE

The present disclosure relates to acoustic filters that employ acoustic resonators and in particular to improved low-loss non-adjacent-band rejection filter topologies.

### BACKGROUND

Connectivity products are constantly required to improve performance in a smaller size and reduced cost to remain competitive in the most challenging projects. This implies reducing the loss of the signal path while providing sufficient out-of-band rejection. The more out-of-band rejection an application requires, the higher the signal path loss will be. In addition, the closer to the passband a rejection specification is, the more it will degrade loss and impedance variation.

Typically, out-of-band rejections are achieved with either inductor-capacitor (LC) tanks or low-pass/high-pass filtering sections. Bulk acoustic wave (BAW) ladder filters are very effective in dealing with rejections very close to the passband and can deal with other requirements by adding inductors to the topology (a sort of LC tank). Since inductors are required, they tend to limit the overall performance since the achievable Q is much lower than for the capacitors (or BAW resonators). Ultimately, this means the passband loss vs. the required rejection ratio is rather constant. Finding ways to reduce the passband loss while maintaining out-of-band rejections is a very challenging problem. Therefore, a need remains for improved filter circuitry.

### SUMMARY

Filter circuitry having a passband filter configured to pass a desired frequency band, and a filter coupled to the passband filter is disclosed. The filter has at least one acoustic wave resonator configured to attenuate an undesired frequency band that is nonadjacent to the desired frequency band. The at least one acoustic resonator behaves as a capacitor at the passband frequencies of the coupled filter. The at least one acoustic resonator may be a bulk acoustic wave resonator.

In another aspect, any of the foregoing aspects individually or together, and/or various separate aspects and features as described herein, may be combined for additional advantage. Any of the various features and elements as disclosed herein may be combined with one or more other disclosed features and elements unless indicated to the contrary herein.

Those skilled in the art will appreciate the scope of the present disclosure and realize additional aspects thereof after reading the following detailed description of the preferred embodiments in association with the accompanying drawing figures.

### BRIEF DESCRIPTION OF THE DRAWING FIGURES

The accompanying drawing figures incorporated in and forming a part of this specification illustrate several aspects of the disclosure and, together with the description, serve to explain the principles of the disclosure.

FIG. 1A is a graph that shows the equivalent capacitance as a function of frequency of a capacitor and the equivalent capacitance as a function of frequency of a bulk acoustic wave (BAW) resonator.

FIG. 1B is a graph that shows the modulus of the input impedance of a capacitor and the modulus of the input impedance of a BAW resonator.

FIG. 2A is a diagram showing the topology of a typical output matching network of a power amplifier with differential output stage.

FIG. 2B is a diagram showing the same output matching network replacing the shunt capacitor to the right with a BAW resonator.

FIG. 2C is a graph showing the transmission coefficient of both networks for a 3.7 GHz 5G band (3300-4200 MHz) application.

FIG. 3A is a schematic of exemplary filter circuitry and an associated frequency response, wherein the filter circuitry is configured to filter the 3.7 GHz 5G band.

FIG. 3B is a schematic of filter circuitry that has similar topology except for a filter section that employs capacitors in place of the resonators.

FIGS. 4A and 4B are graphs that compare the simulated performance of the topology shown in FIG. 3A with the 3.7 GHz 5G band filter that has been used in UHB devices implemented in integrated passive device technology.

FIG. 4C is a graph which shows the small signal measured characterization results where the 0.5 dB LBE improvement is visible.

FIG. 5A is a graph showing gain versus frequency within the n77 band.

FIG. 5B is a graph showing maximum evolved universal terrestrial radio access (EUTRA) adjacent channel leakage ratio (ACLR).

FIG. 5C is a graph showing the power amplifier (PA) current consumption versus frequency.

FIG. 5D is a graph showing error vector magnitude (EVM) versus frequency.

FIG. 6A is a diagram showing a simple low-pass matching network between two circuits comprised of an inductor and a shunt capacitor.

FIG. 6B is a diagram showing the circuit of FIG. 6A in which the capacitor has been replaced by an acoustic resonator to create a transmission zero.

FIG. 6C is a diagram showing a series inductor-capacitor (LC) tank to ground and the same circuit when the capacitor has been replaced by an acoustic resonator.

FIG. 6D is a diagram showing a more complex matching network comprised of two capacitors to ground and a series parallel LC tank and a version where one of the shunt capacitors has been replaced by an acoustic resonator.

FIG. 7 is a spectrum graph depicting gaps between nonadjacent frequency bands that include wireless fidelity (WiFi) and ultrawide-band

FIG. 8 is a spectrum graph depicting gaps between ultra-high-band (UHB) frequencies.

FIG. 9 is a spectrum graph depicting gaps between bands B25, B66, B30, and B7.

FIG. 10 is a spectrum graph depicting gaps between bands B1, B3, B40, and B7.

FIG. 11 is a spectrum graph depicting gaps between bands within Unlicensed National Information Infrastructure (UNII) spectrum.

FIG. 12 is a diagram showing how the disclosed filter circuitry may interact with user elements such as wireless communication devices.

### DETAILED DESCRIPTION

The embodiments set forth below represent the necessary information to enable those skilled in the art to practice the embodiments and illustrate the best mode of practicing the embodiments. Upon reading the following description in light of the accompanying drawing figures, those skilled in the art will understand the concepts of the disclosure and will recognize applications of these concepts not particularly addressed herein. It should be understood that these concepts and applications fall within the scope of the disclosure and the accompanying claims.

It will be understood that, although the terms first, second, etc. may be used herein to describe various elements, these elements should not be limited by these terms. These terms are only used to distinguish one element from another. For example, a first element could be termed a second element, and, similarly, a second element could be termed a first element, without departing from the scope of the present disclosure. As used herein, the term “and/or” includes any and all combinations of one or more of the associated listed items.

It will be understood that when an element such as a layer, region, or substrate is referred to as being “on” or extending “onto” another element, it can be directly on or extend directly onto the other element or intervening elements may also be present. In contrast, when an element is referred to as being “directly on” or extending “directly onto” another element, there are no intervening elements present. Likewise, it will be understood that when an element such as a layer, region, or substrate is referred to as being “over” or extending “over” another element, it can be directly over or extend directly over the other element or intervening elements may also be present. In contrast, when an element is referred to as being “directly over” or extending “directly over” another element, there are no intervening elements present. It will also be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present.

Relative terms such as “below” or “above” or “upper” or “lower” or “horizontal” or “vertical” may be used herein to describe a relationship of one element, layer, or region to another element, layer, or region as illustrated in the Figures. It will be understood that these terms and those discussed above are intended to encompass different orientations of the device in addition to the orientation depicted in the Figures.

The terminology used herein is for the purpose of describing particular embodiments only and is not intended to be limiting of the disclosure. As used herein, the singular forms “a,” “an,” and “the” are intended to include the plural forms as well, unless the context clearly indicates otherwise. It will be further understood that the terms “comprises,” “comprising,” “includes,” and/or “including” when used herein specify the presence of stated features, integers, steps, operations, elements, and/or components, but do not preclude the presence or addition of one or more other features, integers, steps, operations, elements, components, and/or groups thereof.

Unless otherwise defined, all terms (including technical and scientific terms) used herein have the same meaning as commonly understood by one of ordinary skill in the art to which this disclosure belongs. It will be further understood that terms used herein should be interpreted as having a meaning that is consistent with their meaning in the context of this specification and the relevant art and will not be interpreted in an idealized or

Embodiments are described herein with reference to schematic illustrations of embodiments of the disclosure. As such, the actual dimensions of the layers and elements can be different, and variations from the shapes of the illustrations as a result, for example, of manufacturing techniques and/or tolerances, are expected. For example, a region illustrated or described as square or rectangular can have rounded or curved features, and regions shown as straight lines may have some irregularity. Thus, the regions illustrated in the figures are schematic and their shapes are not intended to illustrate the precise shape of a region of a device and are not intended to limit the scope of the disclosure. Additionally, sizes of structures or regions may be exaggerated relative to other structures or regions for illustrative purposes and, thus, are provided to illustrate the general structures of the present subject matter and may or may not be drawn to scale. Common elements between figures may be shown herein with common element numbers and may not be subsequently re-described.

Disclosed are embodiments that are configured to minimize loss penalties of implementing out-of-band rejections by employing acoustic resonance or anti-resonance of bulk acoustic wave resonators. This concept is applied to an ultra-high band 3.7 GHz 5G band filter, which is implemented in integrated passive device technology. Simulation and measured results show a 0.5 dB improvement in low-band edge loss for the same out-of-band rejection levels. This improvement translates in a substantially reduced current consumption of at least 80 mA at a module level.

A notable element of the embodiments according to the present disclosure is a bulk acoustic wave (BAW) resonator with a resonant or anti-resonant frequency configured to provide rejection at a non-adjacent band of a desired operating band.

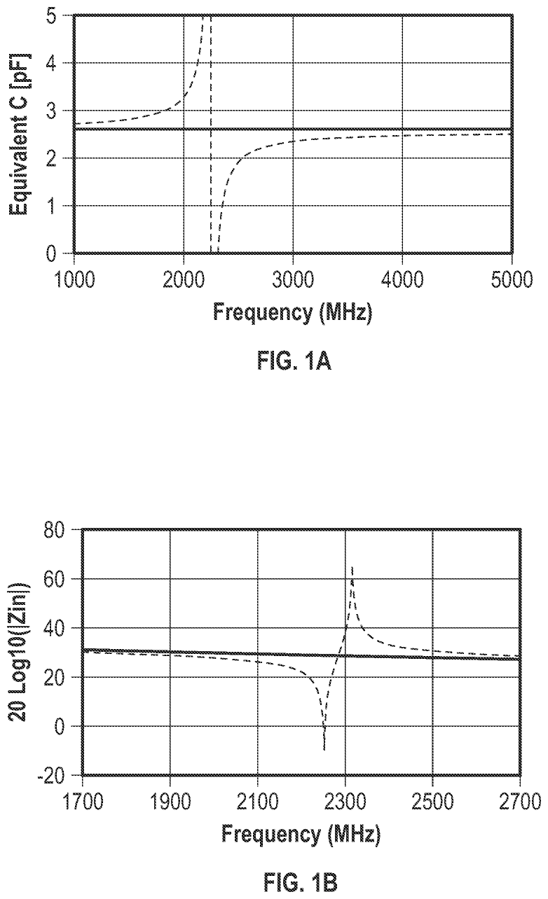

BAW resonators are devices that are usable to create out-of-band rejection notches by way of their resonance or anti-resonance at a much lower passband loss cost because there is no requirement for a low quality (Q) factor inductor, wherein a low Q factor is defined to be less than 50. A Q factor of ~700 for BAW devices employed for illustrating exemplary performance of BAW devices is shown in a graph in FIG. 1A and a graph in FIG. 1B. In the graph of FIG. 1A, the equivalent capacitance as a function of frequency of a capacitor is depicted in solid line and the equivalent capacitance as a function of frequency of a BAW resonator is depicted in dashed line. In the graph of FIG. 1B, the modulus of the input impedance of a capacitor is depicted in solid line and the impedance of a BAW resonator is depicted is dashed line.

BAW resonators may be thought of as a frequency-dependent capacitor featuring a zero and a pole. FIG. 1A and FIG. 1B show these properties. FIG. 1A depicts the equivalent capacitance of a BAW resonator, and FIG. 1B shows the modulus of the input impedance. At resonance, a BAW resonator presents very low impedance, and at the anti-resonance, it has a very high impedance. These properties make BAW resonators interesting circuit elements in that the BAW resonators may behave as high-Q open circuits and short circuits may be used to create out-of-band rejection notches while in the passband a BAW resonator behaves like a coupling capacitor.

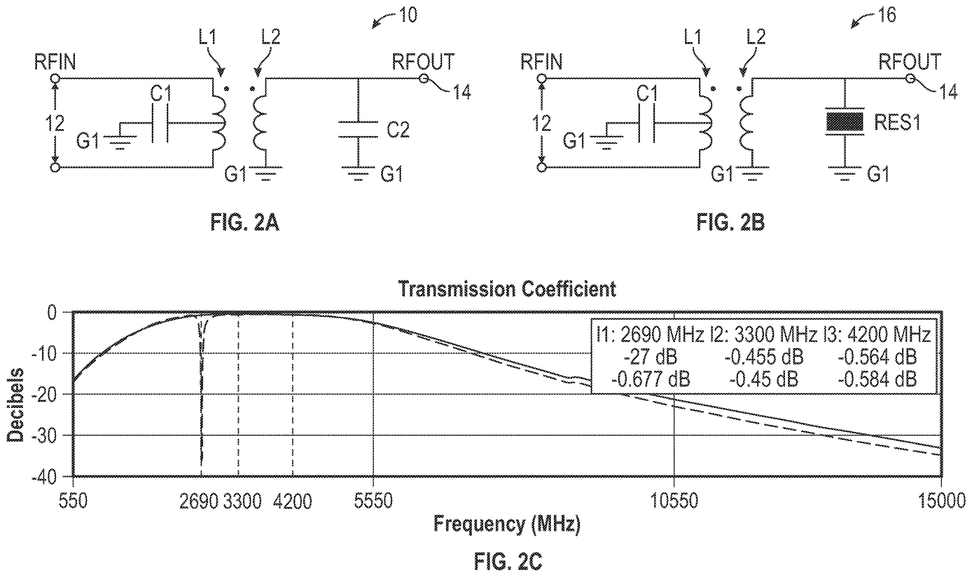

As an example, FIG. 2A shows the topology of the output matching network 10 used in several generations of the ultra-high-band (UHB) power amplifier-duplexer modules (PADs). A differential power amplifier output stage (not shown) is typically connected to a radio frequency input 12, labeled RFIN, which in turn is coupled to a primary coil L1 that is magnetically coupled to a secondary coil L2. A first capacitor C1 is between a center tap of primary coil L1 and a fixed voltage node G1 that is typically ground. An RF output 14, labeled RFOUT, is coupled to the secondary coil L2. To bring the impedance of the resulting circuit close to 50 Ω, a shunt capacitor is used typically known as a secondary capacitor C2. FIG. 2B depicts an output matching network that in the form of filter circuitry 16 that replaces the secondary capacitor C2, a surface-mount device (SMD), with an appropriately chosen BAW resonator RES1.

FIG. 2C compares a transmission coefficient of the output matching network of FIG. 2A depicted in solid line with a transmission coefficient of the filter circuitry 16 depicted FIG. 2B in dashed lines. Both the solid line and the dashed line show similar performance except for the added acoustic resonance at 2690 MHz. Note that the addition of this notch does not increase the insertion loss at the 3.7 GHz 5G band frequencies. Another consideration is the tolerance of the secondary capacitor C2 compared with the BAW resonator RES1. For the range of values typically used for a secondary capacitor C2, the SMD tolerance is in the 10% range, but capacitance of a BAW resonator is expected to vary only 5%.

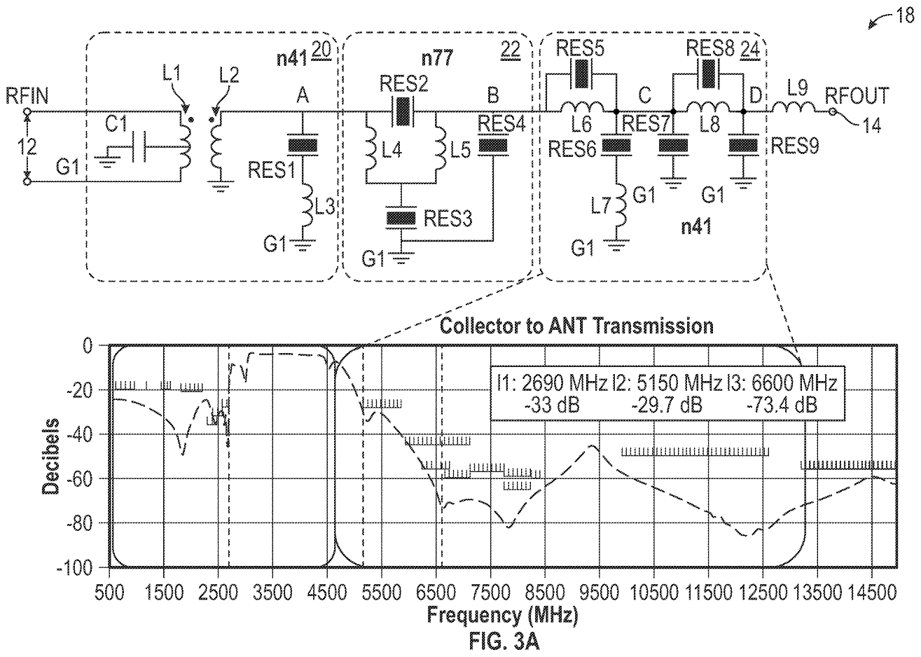

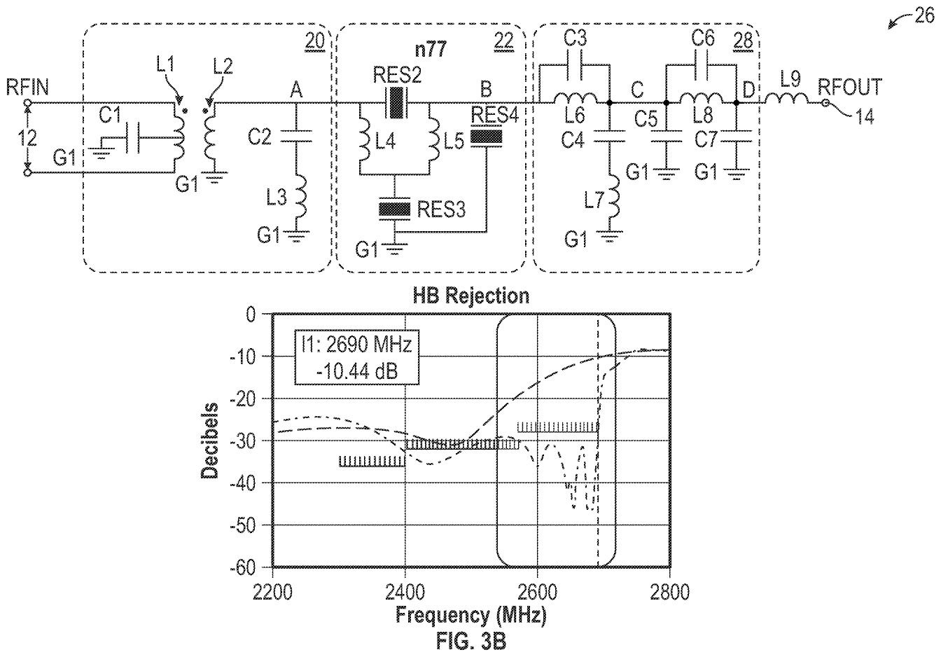

The notch in the foregoing example was placed at 2690 MHz, which is the highest frequency a 3.7 GHz 5G band filter needs to provide rejection for coexistence with the high bands (HBs). This notch is not enough to cover the entire HB frequency range. In this regard, FIG. 3A is a schematic of exemplary filter circuitry 18 and an associated frequency response graph, wherein the filter circuitry is configured to filter the 3.7 GHz 5G band. A first filter section 20, similar to FIG. 2B, is a balanced-to-unbalanced transformer configured to create a notch at the n41 band, a second filter section 22 is an n77 passband filter, and a third filter section 24 is configured as a low-pass filter with transmission zeros at the n41 band in this exemplary embodiment. The first filter section 20, the second filter section 22, and the third filter section 24 are coupled in series between the secondary coil L2 and the output 14, RFOUT. The first filter section 20 has a first resonator RES1 coupled in series with a third coil L3 between a first node A and the fixed voltage node G1.

The second filter section 22 has a second resonator RES2 coupled in series between the first node A and a second node B. A third resonator RES3 is coupled in series with a fourth inductor L4 between the first node A and the fixed voltage node G1. A fifth inductor L5 is coupled between the second node B and the third resonator RES3, and a fourth resonator RES4 is coupled between the second node B and the fixed voltage node G1.

The third filter section 24 has a fifth resonator RES5 coupled in parallel with a sixth inductor L6 between the second node B and a third node C. A seventh RES7 is coupled in series with a seventh inductor L7 between the third node C and the fixed voltage node G1. An eighth resonator RES8 is coupled in parallel between the third node C and a fourth node D. A ninth resonator RES9 between the fourth node D and the fixed voltage node G1. A ninth inductor L9 is coupled between the fourth node D and the RF output 14, RFOUT.

The embodiment of FIG. 3A is configured for using 2.5 GHz 5G band resonators to implement the high band rejection, where each resonator can have a different resonant frequency even if not explicitly shown in FIG. 3A. For example, in some embodiments, the resonators RES5 to RES9 are BAW resonators configured for operation in the 3.7 GHz 5G band. Moreover, it should be noted that the topology depicted in FIG. 3A uses two different BAW stacks because of the significantly different resonant frequencies required for the out-of-band notches. The concept according to the present disclosure applies to notches at frequencies not belonging to the directly adjacent bands. Typically, this implies that out-of-band rejection cannot be implemented with the nominal stack for that band, but a resonator stack may be configured to cover these frequencies.

FIG. 3B is a schematic of filter circuitry 26 that has similar topology to filter circuitry 18 (FIG. 3A) except for a low-pass filter section 28 that employs capacitors C3, C4, C5, C6, and C7 in place of the resonators RES5, RES6, RES7, RES8, and RES9, respectively. In the graph of FIG. 3B a dot-dashed line represents the topology shown in FIG. 3A and a long-dashed line represents the 3.7 GHz 5G band transmit filter shown in FIG. 3B. The long-dashed line represents the rejection that the topology of FIG. 3B achieves, the dot-dashed line represents the frequency response that is achieved after replacing the capacitors with 2.5 GHz 5G band resonators as depicted in the embodiment of FIG. 3A. More than a 20 dB improvement is achieved at the highest frequency without degrading passband loss.

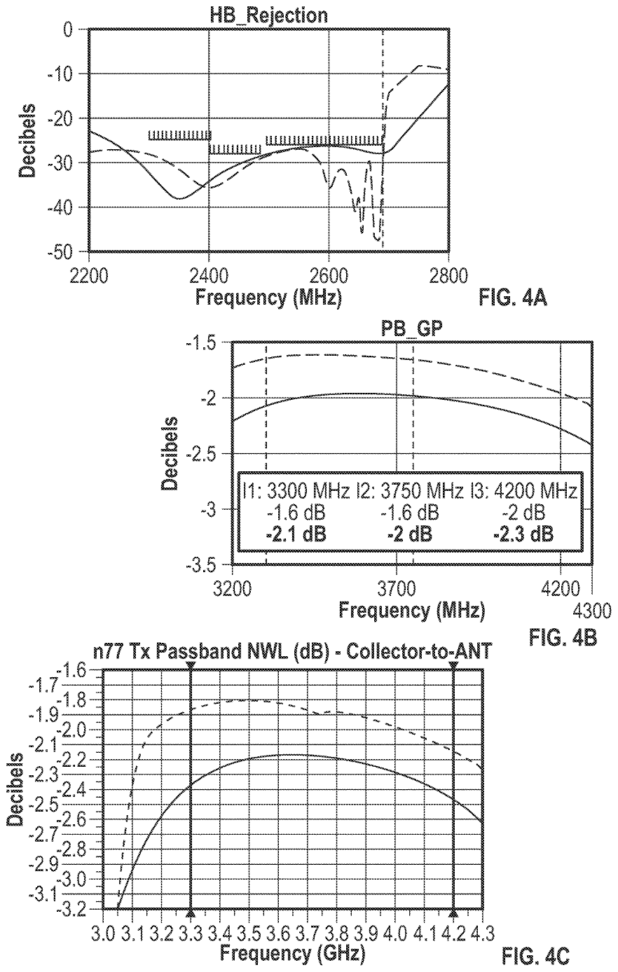

FIGS. 4A and 4B compare the simulated performance of the topology shown in FIG. 3A with the 3.7 GHz 5G band filter that has been used in UHB devices implemented in integrated passive device technology. FIG. 4A shows the HB frequency range where it can be observed how the acoustic notches, depicted in long dashed line, replace the low-Q LC tank notch of the solid line around 2690 MHz.

FIG. 4B is a graph depicting a simulated passband performance delta between the filter circuitry 18 of FIG. 3A and the previously used filter implemented in integrated passive device technology. The typical response is depicted in solid line with representative decibel levels in bold text for three different frequencies. The lower band edge (LBE) loss is 0.5 dB better as represented by a long-dashed line for the same HB rejection level with representative decibel levels in normal text for the three different frequencies.

FIG. 4C shows that the small signal measured characterization results where the 0.5 dB LBE improvement is visible.

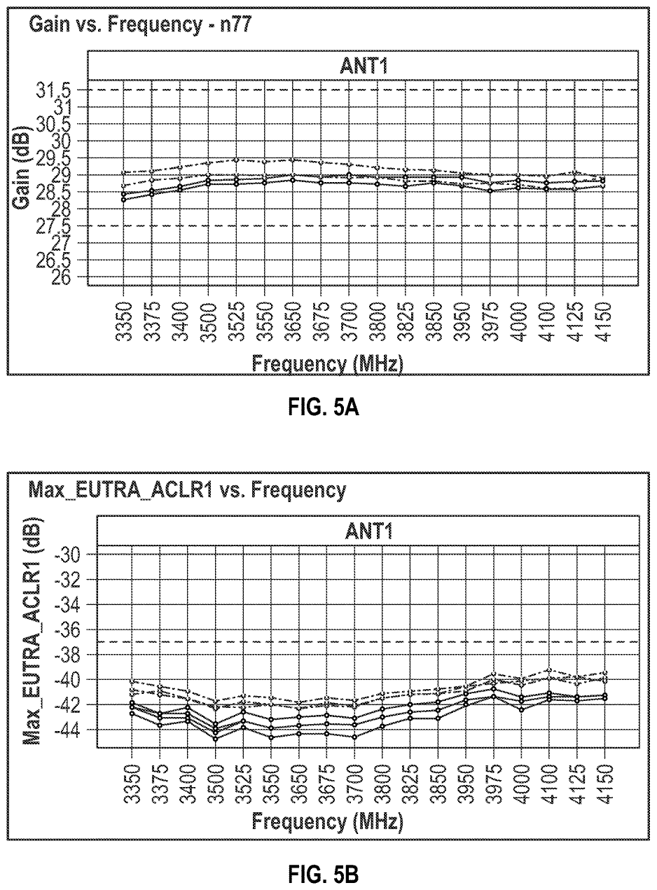

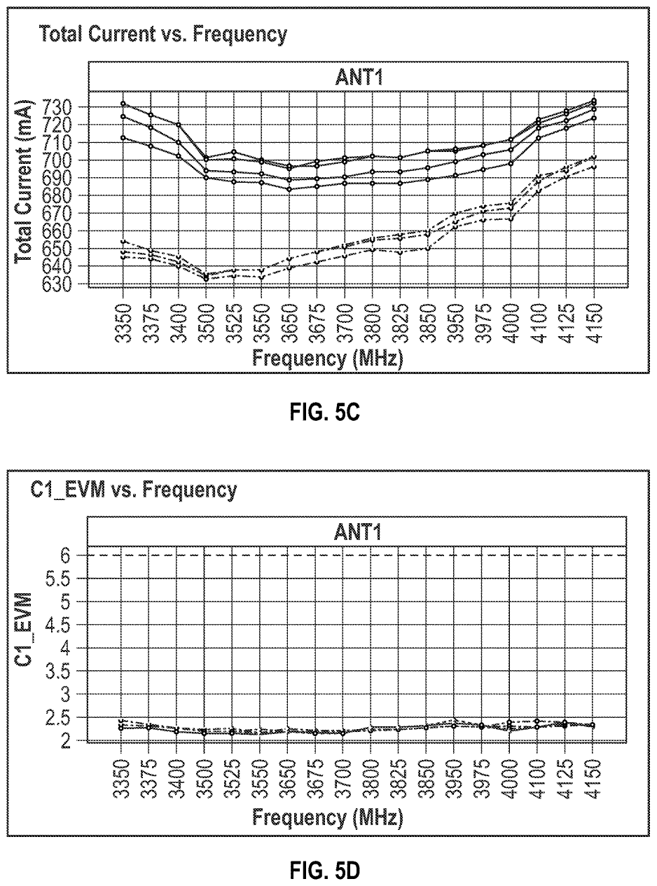

FIG. 5A is a graph showing gain versus frequency within the n77 band. FIG. 5C is a graph showing total current consumption versus frequency. FIG. 5B is a graph showing maximum evolved universal terrestrial radio access (EUTRA) adjacent channel leakage ratio (ACLR). FIG. 5D is a graph showing error vector magnitude (EVM) versus frequency. Dot-dashed lines in the graphs represent performance of resonator-based filter circuitry of the present disclosure and corresponding solid lines represent performance of the previously used filter implemented in integrated passive device technology. In general, FIG. 5A through FIG. 5D show a large signal comparison for MPRO modulation. For the same gain, adjacent channel leakage ratio, and error vector magnitude, the filter using the concept according to the present disclosure shows an average improvement of 60 mA, compared with the integrated passive device.

The main challenge to successfully implement the concept according to the present disclosure in a design is ensuring that the additional acoustic stack modes of the additional dies, such as the mirror mode or high-frequency overtones, do not land in a critical frequency range of the target band.

To sum up, the present disclosure relates to how the resonances of acoustic devices can be used to implement out-of-band notches at a virtually zero passband loss cost. These out-of-band notches are defined as frequencies belonging to bands not directly adjacent to the main passband.

Alternative implementations of the concept according to the present disclosure extend beyond the topologies shown in FIG. 2B or FIG. 3A. In general, any network can be used where an acoustic resonator is used to create a transmission zero.

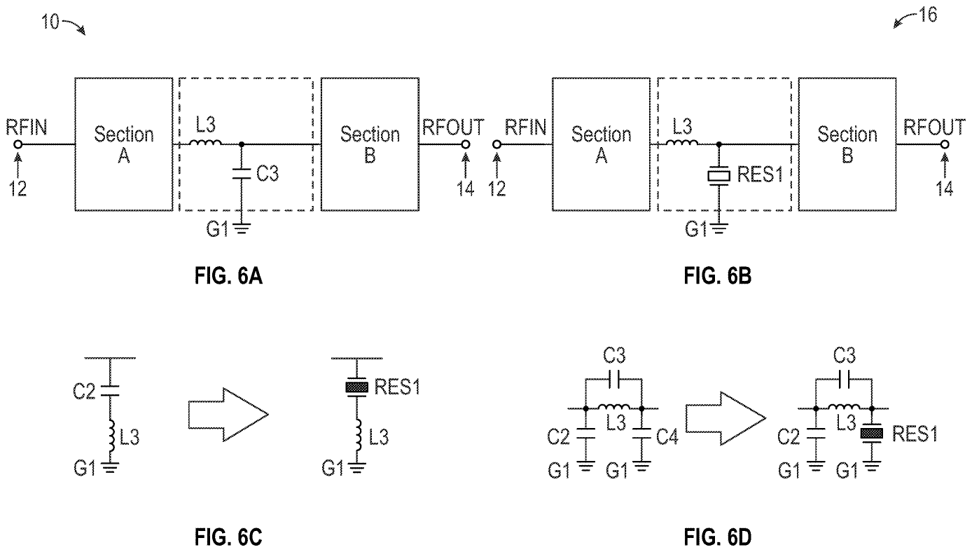

FIG. 6A shows a simple low-pass network 10 between two generic circuit sections A and B implemented with an inductor L3 and a capacitor C3. FIG. 6B shows the same network where the shunt capacitor C3 has been replaced by an acoustic resonator RES1 to create an out-of-band notch. The behavior of the second circuit in the passband of interest is the same as the one of FIG. 6A but it features additional rejection. FIG. 6C shows that the capacitors of LC tanks can also be replaced by acoustic resonators for the same purpose. Finally, FIG. 6D shows a more complex matching network where at least one of the capacitors has been replaced.

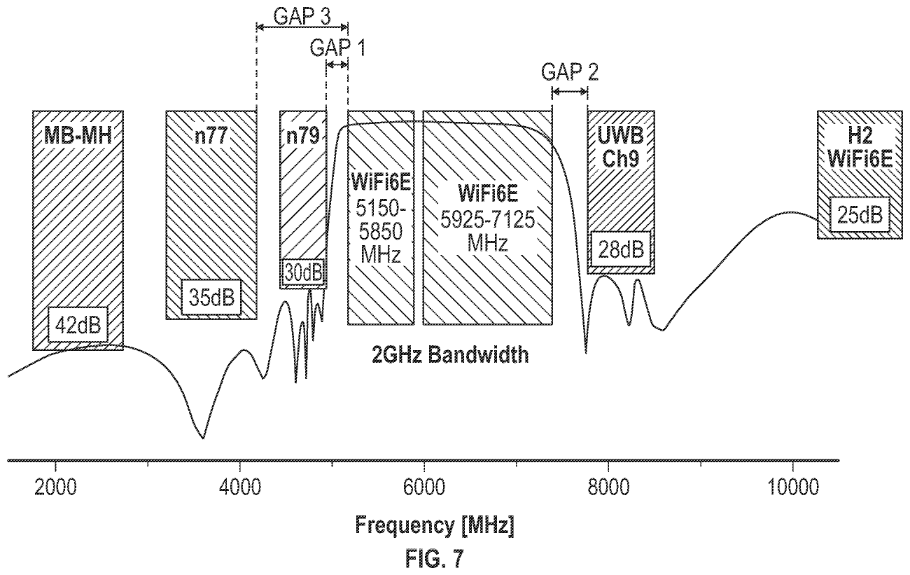

FIG. 7 is a spectrum graph depicting gaps between nonadjacent frequency bands that include wireless fidelity (WiFi) and ultrawide-band (UWB) frequencies. A thicker solid black line depicts frequency response of a WiFi 6 enhanced (WiFi6E) passband filter and the adjacent bands are n7 (below) and UWB (above). As shown, the thicker black line has multiple sharp acoustic notches configured to achieve the required rejection level. The non-adjacent bands here are MB-MH and n77 both of which are below the WiFi6E band. The rejection required for these bands may be achieved by inductor-capacitor (LC) notches.

In this case, the traditional filter employs acoustic notches to achieve the n79 and UWB rejections (adjacent bands) and LC notches for the required n77 rejection (non-adjacent band). The present disclosure proposes the replacement of those LC notches with an appropriate topology that uses acoustic resonances to implement the n77 rejection. A first gap 1 between n79 and WiFi6E is 3% and a second gap 2 between WiFi6E and UWB is ~7%. A third gap 3 is between WiFi6E and n77 non-adjacent case is 22%.

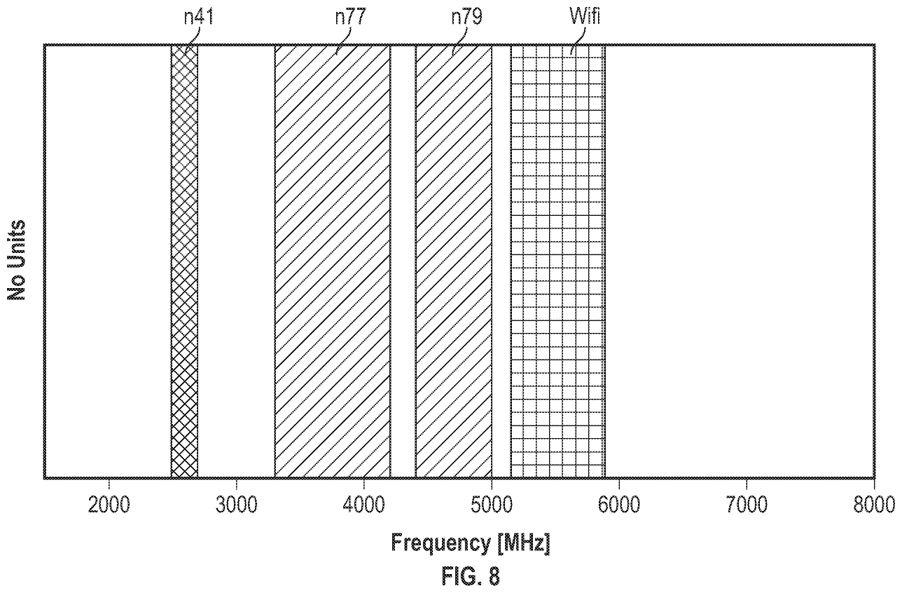

FIG. 8 is a spectrum graph depicting gaps between ultra-high-band (UHB) frequencies. The n77 and n79 bands have a ~5% gap percentage and a gap percentage between n79 and WiFi6E is 3%. In accordance with the present disclosure, rejection notches employing acoustic wave resonators are placed at the n41 frequencies to achieve an n77 filter. The gap percentage is ~22%. Moreover, the gap percentage between the n77 and WiFi6E is 22%.

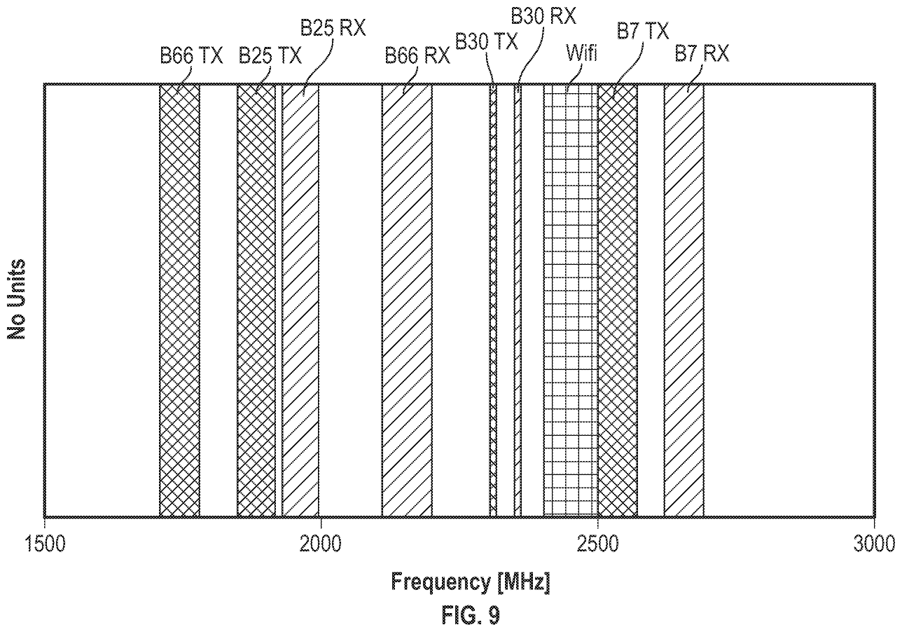

FIG. 9 is a spectrum graph depicting gaps between bands B25, B66, B30, and B7. Typically, two B25 filters employ acoustic resonators to provide rejection to each other. The gap between the bands is 15 MHz with a gap percentage of ~0.8%. A B25TX filter is configured also to reject bands B66RX and B30RX or B7RX, but those are relatively far away, having gap percentages of about ~10%, ~23%, and ~37%. B7 filters are configured to reject each other with the gap percentage being ~2%. The gap percentage between the B30 filters is ~1.5%, while the gap percentage between B30RX and WiFi6E is ~1.7%. Between B30TX and B66RX there is a ~5% distance but this rejection is not typically achieved with acoustic notches. Further examples of gap percentages of non-adjacent bands within the spectrum depicted in FIG. 9 are as follows: B66TX to B25RX ~8.5%, B7TX to B30RX ~8.2%, B30TX to B25RX ~15%, and B7RX to WiFi6E ~9%.

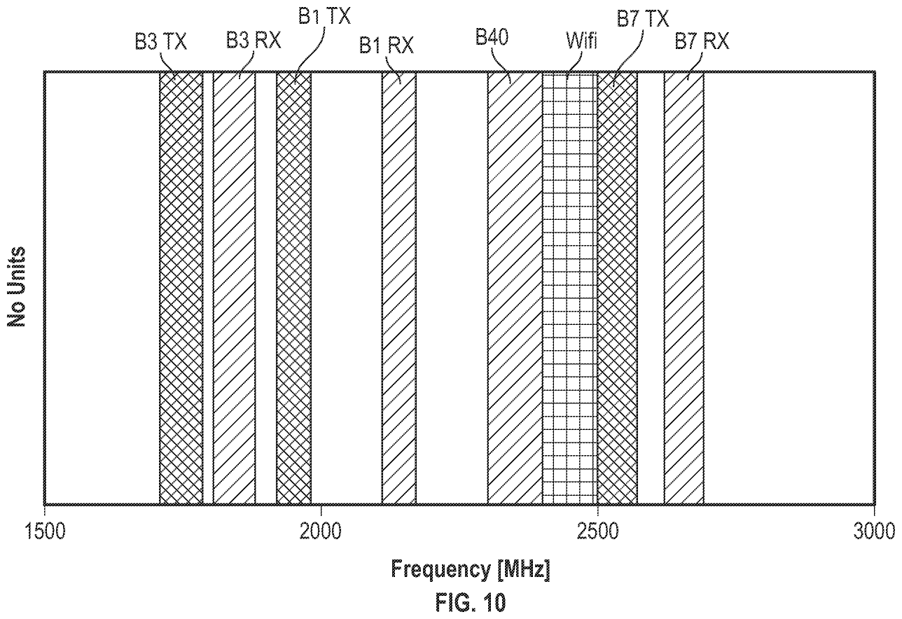

FIG. 10 is a spectrum graph depicting gaps between bands B1, B3, B40, and B7. The gap percentage is 1.1% for band B3 while the gap percentage between bands B1TX and B3RX is 1.6%. The gap percentage between bands B40 to WiFi 2440 MHz is 1.7%. The gap percentage between bands B7TX and WiFi 2477 MHz is ~1%. The bands B1TX to B1RX having a gap percentage of ~6.5% do not presently employ acoustic resonances.

Further examples of gap percentages of non-adjacent bands within the spectrum depicted in FIG. 10 are as follows: B1TX to B40 is 16%, B7TX to B40 is ~4%, and B7RX to WiFi is ~5%.

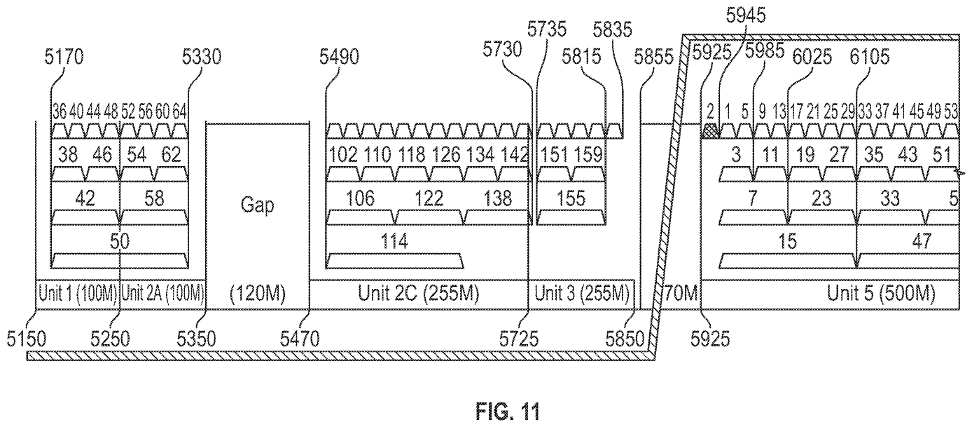

FIG. 11 is a spectrum graph depicting gaps between bands within Unlicensed National Information Infrastructure (UNII) spectrum. The gap percentages within the UNII spectrum are 1.3% and 2.2%. Further examples of gap percentages of adjacent bands within the low band spectrum are as follows: B12/n85 is 1.7%, B13/B14 is 1.1%, B28 is 1.3%, B20 is 1.3%, B26 is 1.2%, B8 is 1.1%, B11/B21 is 0.9%, and B71/n105 is 1.7%.

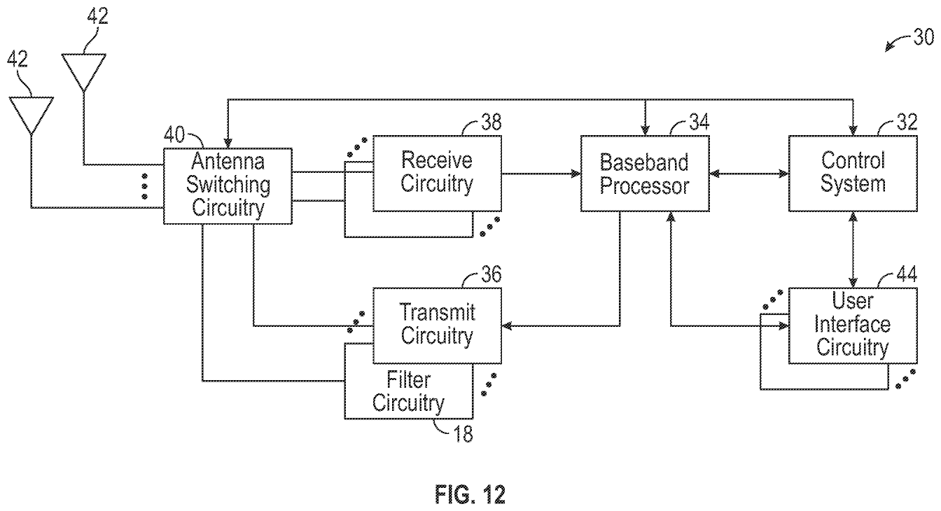

With reference to FIG. 12, the concepts described above may be implemented in various types of wireless communication devices or user elements 30, such as mobile terminals, smart watches, tablets, computers, navigation devices, access points, and the like that support wireless communications, such as cellular, wireless local area network (WLAN), Bluetooth, and near-field communications. The user elements 30 will generally include a control system 32, a baseband processor 34, transmit circuitry 36 that includes the filter circuitry 18, receive circuitry 38, antenna switching circuitry 40, multiple antennas 42, and user interface circuitry 44. The receive circuitry 38 receives radio frequency signals via the antennas 42 and through the antenna switching circuitry 40 from one or more basestations. A low-noise amplifier and a filter (not shown) cooperate to amplify and remove broadband interference from the received signal for processing.

Downconversion and digitization circuitry (not shown) will then downconvert the filtered, received signal to an intermediate or baseband frequency signal, which is then digitized into one or more digital streams.

The baseband processor 34 processes the digitized received signal to extract the information or data bits conveyed in the received signal. This processing typically comprises demodulation, decoding, and error correction operations. The baseband processor 34 is generally implemented in one or more digital signal processors (DSPs) and application-specific integrated circuits (ASICs).

For transmission, the baseband processor 34 receives digitized data, which may represent voice, data, or control information, from the control system 32, which it encodes for transmission. The encoded data are output to the transmit circuitry 36, where they are used by a modulator (not shown) to modulate a carrier signal that is at a desired transmit frequency or frequencies. A power amplifier (not shown) will amplify the modulated carrier signal to a level appropriate for transmission and deliver the modulated carrier signal to the antennas 42 through the antenna switching circuitry 40. The antennas 42 and the replicated transmit circuitry 36 and receive circuitry 38 may provide spatial diversity. Modulation and processing details will be understood by those skilled in the art.

It is contemplated that any of the foregoing aspects, and/or various separate aspects and features as described herein, may be combined for additional advantage. Any of the various embodiments as disclosed herein may be combined with one or more other disclosed embodiments unless indicated to the contrary herein.

Those skilled in the art will recognize improvements and modifications to the preferred embodiments of the present disclosure. All such improvements and modifications are considered within the scope of the concepts disclosed herein and the claims that follow.

1. A filter circuitry comprising:
a passband filter configured to pass a desired frequency band; and
a filter coupled to the passband filter, wherein the filter comprises at least one acoustic wave resonator configured to attenuate an undesired frequency band that is nonadjacent to the desired frequency band, wherein a gap between the undesired frequency band that is nonadjacent to the desired frequency band has a gap percentage that is equal to a gap that is a difference between the desired frequency band and the undesired frequency band divided by a lowest frequency of the gap.

2. The filter circuitry of claim 1 wherein the acoustic wave resonator is a bulk acoustic wave resonator.

3. (canceled)

4. The filter circuitry of claim 1 wherein the gap percentage is between 0.8% and 3%.

5. The filter circuitry of claim 1 wherein the gap percentage is between 3% and 7%.

6. The filter circuitry of claim 1 wherein the gap percentage is between 7% and 10%.

7. The filter circuitry of claim 1 wherein the gap percentage is between 10% and 15%.

8. The filter circuitry of claim 1 wherein the gap percentage is between 15% and 23%.

9. The filter circuitry of claim 1 wherein the gap percentage is at least 23%.

10. A wireless communication device comprising:
a baseband processor; and
transmit circuitry configured to receive encoded data from the baseband processor and to modulate a carrier signal with the encoded data, wherein the transmit circuitry comprises:
a passband filter configured to pass a desired frequency band; and
a filter coupled to the passband filter, wherein the filter comprises at least one acoustic wave resonator configured to attenuate an undesired frequency band that is nonadjacent to the desired frequency band, wherein a gap between the undesired frequency band that is nonadjacent to the desired frequency band has a gap percentage that is equal to a gap that is a difference between the desired frequency band and the undesired frequency band divided by a lowest frequency of the gap.

11. The wireless communication device of claim 10 wherein the acoustic wave resonator is a bulk acoustic wave resonator.

12. (canceled)

13. The wireless communication device of claim 10 wherein the gap percentage is between 0.8% and 3%.

14. The wireless communication device of claim 10 wherein the gap percentage is between 3% and 7%.

15. The wireless communication device of claim 10 wherein the gap percentage is between 7% and 10%.

16. The wireless communication device of claim 10 wherein the gap percentage is between 10% and 15%.

17. The wireless communication device of claim 10 wherein the gap percentage is between 15% and 23%.

18. The wireless communication device of claim 10 wherein the gap percentage is at least 23%.

19. A method of filtering radio frequency signals comprising:
determining a gap percentage, where the gap percentage is equal to a gap that is a difference between a desired frequency band and the undesired frequency band divided by a lowest frequency of the gap, and setting the gap percentage to be between 0.8% and at least 23%;
filtering the desired frequency band using a passband filter; and
attenuating the undesired frequency band that is nonadjacent to the desired frequency band using at least one acoustic wave resonator, the acoustic wave resonator being coupled to the passband filter.

20. The method of claim 19 wherein the acoustic wave resonator is a bulk acoustic wave resonator.

21. (canceled)

22. The method of claim 19 further comprising determining a gap percentage, where the gap percentage is equal to a gap that is a difference between the desired frequency band and the undesired frequency band divided by a lowest frequency of the gap, and setting the gap percentage to be between 3% and 7%.

23. The method of claim 19 further comprising determining a gap percentage, where the gap percentage is equal to a gap that is a difference between the desired frequency band and the undesired frequency band divided by a lowest frequency of the gap, and setting the gap percentage to be between 7% and 10%.

24. The method of claim 19 further comprising determining a gap percentage, where the gap percentage is equal to a gap that is a difference between the desired frequency band and the undesired frequency band divided by a lowest frequency of the gap, and setting the gap percentage to be between 10% and 15%.

25. The method of claim 19 further comprising determining a gap percentage, where the gap percentage is equal to a gap that is a difference between the desired frequency band and the undesired frequency band divided by a lowest frequency of the gap, and setting the gap percentage to be between 15% and 23%.

26. (canceled)
